(19) United States
(12) Patent Application Publication
(10) Pub. No.: US 2008/0054359 A1
(43) Pub. Date: Mar. 6, 2008

(54) THREE-DIMENSIONAL SEMICONDUCTOR STRUCTURE AND METHOD FOR FABRICATION THEREOF

(75) Inventors: Haining Yang, Wappingers Falls, NY (US); Thomas W. Dyer, Pleasant Valley, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/469,098

(22) Filed: Aug. 31, 2006

(51) Int. Cl. H01L 27/12; H01L 27/01; H01L 31/0392

(52) U.S. Cl. 257/351

(57) ABSTRACT

A three-dimensional integrated circuit includes a first device located over a substrate. The first device has a first structure that has a minimum linewidth. The first structure is laterally separated from a first alignment mark also located over the substrate. The three-dimensional integrated circuit also includes a second device located over the first device. The second device has a second structure that has the minimum linewidth. No second alignment mark is located laterally separated from the second structure. The first structure and the second structure are registered within the minimum linewidth.

### BACKGROUND

1. Field of the Invention

The invention relates generally to semiconductor structures. More particularly, the invention relates to three-dimensional semiconductor structures.

2. Description of the Related Art

Semiconductor structures include resistors, transistors, diodes and capacitors that are typically arranged to form semiconductor circuits over a semiconductor substrate. The foregoing semiconductor structures that comprise semiconductor circuits have been successfully dimensionally scaled in linewidth for several decades.

In addition to the ongoing trend in horizontal scaling of semiconductor devices, a more recently evolving trend within semiconductor fabrication has been a vertical integration of semiconductor layers comprising semiconductor devices to provide three-dimensional integrated circuits. Such a vertical lamination allows for fabrication of differing types of semiconductor devices having differing types of fabrication processes that may be individually optimized to different semiconductor layers within a three-dimensional semiconductor structure.

Various semiconductor structures having enhanced performance, and methods for fabrication thereof, are disclosed in the semiconductor fabrication art.

For example, Liu et al., in “Performance Advantages of 3-D Digital Integrated Circuits in a Mixed SOI and Bulk CMOS Design Space,” accepted at TCAS II, 2005, pp. 1-5, teaches the results of modeling three-dimensional integrated circuits that include devices fabricated within both partially depleted silicon-on-insulator semiconductor layers and bulk silicon semiconductor layers.

In addition, Topol et al., in “Enabling SOI-Based Assembly Technology for Three-Dimensional (3D) Integrated Circuits (ICs),” 2005 IEEE 0-7803-9269, teaches a three-dimensional integrated circuit that enables short distances between stacked layers, a high interconnect density and an aggressive alignment tolerance. Among other features, the foregoing results are realized through use of a transparent handling substrate when aligning stacked layers within the three-dimensional integrated circuit.

Further, Wei et al., in “Vertically Integrated SOI Circuits for Low-Power and High-Performance Applications,” IEEE Trans. On VLSI Systems, 10(3), 2002, pp. 351-62, teaches three-dimensional integrated circuits that may achieve interconnect layer performance improvements. Within the context of a four semiconductor layer three-dimensional integrated circuit, an interconnect layer performance improvement of about 40 percent may be realized.

Still further, Xue et al., in “Multi-Layers with Buried Structures (MLBS): An Approach to Three-Dimensional Integration,” 2001 IEEE International SOI Conference, pp. 117-18, teaches a semiconductor layer method that may be used to fabricate a three-dimensional integrated circuit at a temperature less than about 450 degrees centigrade. Such a temperature of less than about 450 degrees centigrade allows for manufacturing flexibility when fabricating the three-dimensional integrated circuit.

Finally, although not specifically necessarily directed towards three-dimensional integrated circuits, Fried et al., in U.S. Pat. No. 6,657,259, teaches that both n-finFET devices and p-finFET devices may be fabricated from a single semiconductor substrate with enhanced performance of both the n-finFET devices and the p-finFET devices. The disclosed invention realizes the foregoing object by using n-finFET semiconductor fin structures that are crystallographically angled with respect to p-finFET semiconductor fin structures formed from the single semiconductor substrate.

Semiconductor structure and device dimensions are certain to continue to decrease. As a result thereof desirable are semiconductor structures, including three-dimensional semiconductor structures, that may be fabricated with enhanced performance.

### SUMMARY OF THE INVENTION

The invention includes a three-dimensional semiconductor structure (i.e., an integrated circuit) and a method for fabricating the three-dimensional semiconductor structure. The three-dimensional semiconductor structure is fabricated with enhanced precision by using a single alignment mark for aligning semiconductor structures and optionally also non-semiconductor structures, at all vertical levels within the three-dimensional semiconductor structure.

A semiconductor structure in accordance with the invention includes a first device located over a substrate and having a first structure having a minimum linewidth. The semiconductor structure also includes a second device located over the first device and having a second structure having the minimum linewidth. Within this particular semiconductor structure, an alignment of the first structure with respect to the second structure deviates by no more than the minimum linewidth.

Another semiconductor structure in accordance with the invention includes a first device located over a substrate and having a first structure located laterally separated from a first alignment mark also located over the substrate. This other structure also includes a second device located over the first device and having a second structure absent a second alignment mark located laterally separated from the second structure.

A method in accordance with the invention includes forming over a substrate a first device comprising a first structure. The first structure is laterally separated from a first alignment mark. The method also includes forming over the first device a second semiconductor layer. Finally, the method also includes patterning the second semiconductor layer while using the first alignment mark for aligning a second structure formed from the second semiconductor layer with respect to the first structure. The second structure is used within a second device located over the first device.

Within the embodiment and invention, an “alignment mark” is intended to comprise one or more horizontally separated structures having the same vertical height located over a substrate.

Within the embodiment and the invention, a “device” is intended as including at least one semiconductor structure comprising a monocrystalline silicon material. Preferably the device comprises a field effect device.

Within the embodiment and the invention, a “minimum linewidth” is intended as a minimum measured linewidth that correlates with a minimum photolithographically resolvable linewidth.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 11 show a series of schematic cross-sectional diagrams illustrating the results of progressive stages in fabricating a semiconductor structure in accordance with an embodiment of the invention.

### DESCRIPTION OF THE PREFERRED EMBODIMENT

The invention, which includes a three-dimensional semiconductor structure fabricated with enhanced precision, and a method for fabricating the three-dimensional semiconductor structure with enhanced precision, is understood within the context of the description provided below. The description provided below is understood within the context of the drawings described above. Since the drawings are intended for illustrative purposes, the drawings are not necessarily drawn to scale.

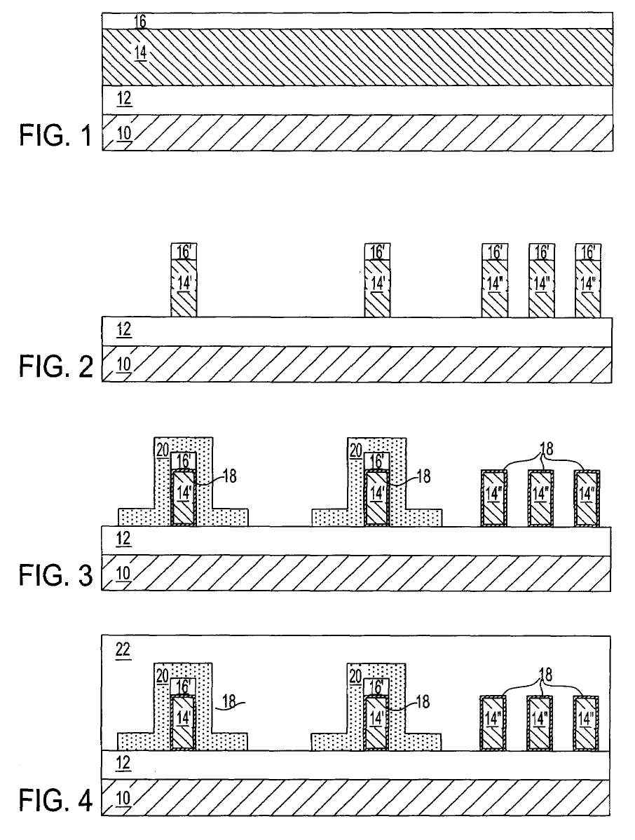

FIG. 1 to FIG. 11 show a series of schematic cross-sectional diagrams illustrating the results of progressive stages in fabricating a semiconductor structure in accordance with an embodiment of the invention. This embodiment of the invention comprises a preferred embodiment of the invention.

FIG. 1 shows a base semiconductor substrate 10. A buried dielectric layer 12 is located upon the base semiconductor substrate 10, and a surface semiconductor layer 14 is located upon the buried dielectric layer 12. Finally, a hard mask layer 16 is located upon the surface semiconductor layer 14. In an aggregate, the base semiconductor substrate 10, the buried dielectric layer 12 and the surface semiconductor layer 14 comprise a semiconductor-on-insulator substrate.

The base semiconductor substrate 10 may comprise any of several semiconductor materials. Non-limiting examples include silicon, germanium, silicon-germanium alloy, silicon carbide, silicon-germanium carbide alloy and compound (i.e., III-V and II-VI) semiconductor materials. Non-limiting examples of compound semiconductor materials include gallium arsenide, indium arsenide and indium phosphide semiconductor materials. Typically, the base semiconductor substrate 10 has a thickness from about 0.2 to about 1 mm.

The buried dielectric layer 12 may comprise any of several dielectric materials. Non-limiting examples include oxides, nitrides and oxynitrides, particularly of silicon. However, oxides, nitrides and oxynitrides of other elements are not excluded. The buried dielectric layer 12 may comprise a crystalline or a non-crystalline dielectric material, with crystalline dielectric materials being highly preferred. The buried dielectric layer 12 may be formed using any of several methods. Non-limiting examples include ion implantation methods, thermal or plasma oxidation or nitridation methods, chemical vapor deposition methods and physical vapor deposition methods. Typically, the buried dielectric layer 12 comprises an oxide of the semiconductor material from which is comprised the semiconductor substrate 10. Typically, the buried dielectric layer 12 has a thickness from about 100 to about 2000 angstroms.

The surface semiconductor layer 14 may comprise any of the several semiconductor materials from which the base semiconductor substrate 10 may be comprised. The surface semiconductor layer 14 and the base semiconductor substrate 10 may comprise either identical or different semiconductor materials with respect to chemical composition, dopant polarity, dopant concentration and crystallographic orientation. Typically, the surface semiconductor layer 14 has a thickness from about 100 to about 1000 angstroms.

The semiconductor-on-insulator substrate that is illustrated in FIG. 1 may be fabricated using any of several methods. Non-limiting examples include lamination methods, layer transfer methods and separation by implantation of oxygen (SIMOX) methods.

Although the embodiment illustrates the invention within the context of a semiconductor on-insulator substrate comprising the base semiconductor substrate 10, the buried dielectric layer 12 and the surface semiconductor layer 14, neither the embodiment, nor the invention in general, is so limited. Rather, the embodiment or the invention may alternatively be practiced using a bulk semiconductor substrate (that would otherwise result from absence of the buried dielectric layer 12 under circumstances where the base semiconductor substrate 10 and the surface semiconductor layer 14 have identical chemical composition and crystallographic orientation). The embodiment and the invention also contemplate use of a hybrid orientation (HOT) substrate that has multiple crystallographic orientations within a single semiconductor substrate.

The hard mask layer 16 may comprise any of several hard mask materials. Included as hard mask materials are the same group of dielectric materials that may be used for forming the buried dielectric layer 12. This group of hard mask materials may also be formed using analogous, equivalent or identical methods to those that are used for forming the buried dielectric layer 12. Typically, the hard mask layer 16 comprises a silicon nitride material that has a thickness from about 300 to about 1000 angstroms.

FIG. 2 shows the results of patterning the hard mask layer 16 located upon the surface semiconductor layer 14 to form the hard mask layers 16′ located upon a plurality of semiconductor fins 14′ and a plurality of alignment marks 14″.

The hard mask layers 16′, the semiconductor fins 14′ and the alignment marks 14″ may be patterned from the hard mask layer 16 and the surface semiconductor layer 14 while using photolithographic and etch methods that are conventional in the semiconductor fabrication art. Such photolithographic and etch methods include, but are not limited to, photolithographic and wet chemical etch methods and photolithographic and dry plasma etch methods. Photolithographic and dry plasma etch methods are generally preferred insofar as they may provide straight or nearly straight sidewalls when etching the hard mask layers 16′, the semiconductor fins 14′ and the alignment marks 14″ from the corresponding hard mask layer 16 and surface semiconductor layer 14.

Particular plasma etch methods will generally use: (1) a fluorine containing etchant gas composition for etching a silicon containing dielectric material from which is typically comprised the hard mask layer 16; and (2) a chlorine containing etchant gas composition for etching a silicon containing semiconductor material from which is typically comprised the surface semiconductor layer 14.

Although not specifically necessarily illustrated within the schematic cross-sectional diagram of FIG. 2, the embodiment contemplates that the semiconductor fins 14′ and the alignment marks 14″ may be formed simultaneously within a single photolithographic and etch process cycle. In an alternative, the embodiment also contemplates that the alignment marks 14″ may be formed in a first photolithographic and etch process step separate from forming the semiconductor fins 14′. The semiconductor fins 14′ may then be formed in a second photolithographic and etch process step separate from the photolithographic and etch process step that is used for forming the alignment marks 14″.

FIG. 3 first shows a plurality of gate dielectrics 18 located upon sidewalls of the semiconductor fins 14′ and the alignment marks 14″. The gate dielectrics 18 may comprise generally conventional gate dielectric materials such as oxides, nitrides and oxynitrides of silicon that have a dielectric constant from about 4 to about 20, measured in vacuum. Alternatively, the gate dielectrics 18 may comprise a generally higher dielectric constant gate dielectric material that has a dielectric constant from about 20 to at least about 100, also measured in vacuum. Such generally higher dielectric constant gate dielectric materials may include, but are not limited to: hafnium oxides, hafnium silicates, titanium oxides, lanthanum oxides, barium-strontium-titantates (BSTs) and lead-zirconate-titanates (PZTs).

The gate dielectrics 18 may be formed using any of several methods that are appropriate to their materials of composition. Included, but not limiting are: thermal or plasma oxidation or nitridation methods, chemical vapor deposition methods (including atomic layer chemical vapor deposition methods) and physical vapor deposition methods (including sputtering methods). Typically, the gate dielectrics 18 comprise a thermal silicon oxide dielectric material that has a thickness from about 10 to about 70 angstroms.

FIG. 3 also shows a plurality of gate electrodes 20 located conformally upon the appropriate gate dielectrics 18 and spanning each of the separate pertinent semiconductor fins 14′.

The gate electrodes 20 may comprise materials including, but not limited to: certain metals, metal alloys, metal nitrides and metal silicides, as well as laminates thereof and composites thereof. The gate electrodes 20 may also comprise doped polysilicon and doped poly silicon-germanium alloy materials (i.e., having a dopant concentration from about 1e18 to about 1 e22 dopant atoms per cubic centimeter) and polycide materials (doped polysilicon (or silicon—germanium alloy)/metal silicide stack materials). Similarly, the foregoing materials may also be formed using any of several methods. Non-limiting examples include salicide methods, chemical vapor deposition methods and physical vapor deposition methods, such as, but not limited to, evaporative methods and sputtering methods. Typically, the gate electrodes 20 comprise a doped polysilicon material that has a thickness from about 500 to about 1500 angstroms.

As is understood by a person skilled in the art, the semiconductor fins 14′, the gate dielectrics 18 and the gate electrodes 20 comprise finFET devices. A channel region within each of the foregoing finFET devices comprises the sidewalls of the individual semiconductor fins 14′. Thus, as illustrated within the schematic cross-sectional diagram of FIG. 3, the finFET devices are double gate finFET devices.

FIG. 3 finally shows the results of stripping the hard mask layers 16′ from the alignment marks 14″. The hard mask layers 16′ may be stripped from the alignment marks 14″ while using methods and materials that are conventional in the semiconductor fabrication art. Included are wet chemical etching methods and materials, and dry plasma etching methods and materials. When the hard mask layers 16′ comprise a silicon nitride hard mask material, the hard mask layers 16′ may be stripped from the alignment marks 14″ absent etching the buried dielectric layer 12 (when typically comprising a silicon oxide material), while using an aqueous phosphoric acid etchant solution at an elevated temperature.

FIG. 4 shows a passivating layer 22 located upon the semiconductor structure of FIG. 3. The passivating layer 22 may comprise any of several dialectic passivating materials. Suitable dielectric passivating materials may be selected from the same group of dielectric passivating materials that are used for forming the buried dielectric layer 12. Also included are crystalline dielectric materials as well as non-crystalline dielectric materials. Further included are generally low dielectric constant passivating dielectric materials (i.e., having a dielectric constant less than about 4) and generally high dielectric constant passivating dielectric materials (i.e., having a dielectric constant greater than about 4). The passivating dielectric materials may also be formed using the same methods and materials that are used for forming the buried dielectric layer 12. Typically, the passivating layer 22 comprises at least in part a silicon oxide passivating material that has a thickness from about 1000 to about 2500 angstroms.

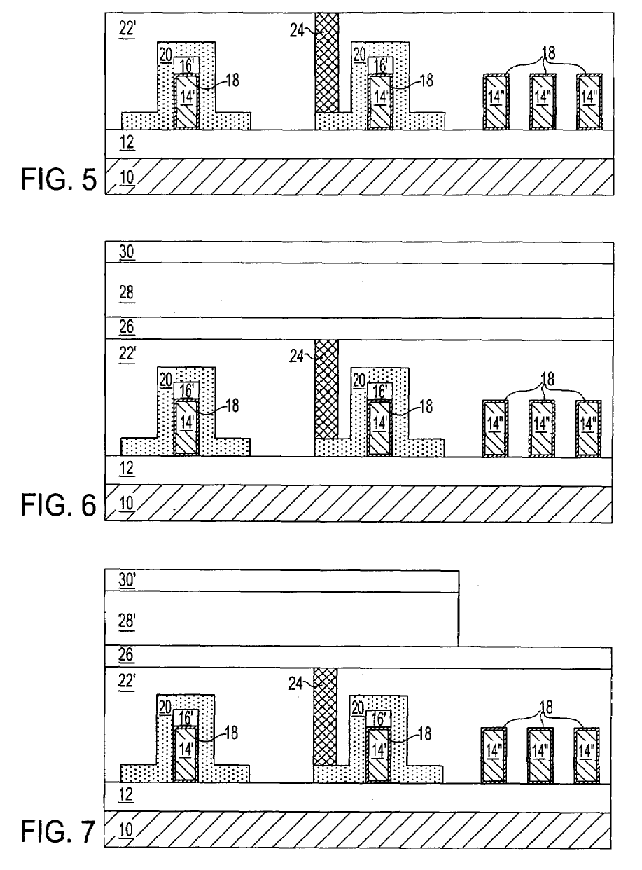

FIG. 5 shows the results of forming an interconnect 24 through the passivating layer 22 that is illustrated in FIG. 4. As a result, a passivating layer 22′ is formed from the passivating layer 22. The interconnect layer 24 may comprise any of several interconnect materials. Common interconnect materials include, but are not limited to metal, metal alloy, metal silicide and metal nitride interconnect materials. The interconnect materials may be formed using any of several methods that are appropriate for their materials of composition. Included are plating methods, chemical vapor deposition methods and physical vapor deposition methods. Also included are mechanical planarizing methods and chemical mechanical polish planarizing methods for forming a planarized interconnect layer 24.

Typically, the interconnect layer 24 comprises a metal, metal alloy, metal silicide or metal nitride conductor material that is formed incident to planarization of a blanket layer of deposited conductor material. Typically, the planarization is effected while using a chemical mechanical polish planarizing method. However, neither the embodiment nor the invention is so limited.

FIG. 6 shows a dielectric capping layer 26 located upon the semiconductor structure of FIG. 5. FIG. 6 also shows a second surface semiconductor layer 28 located upon the dielectric capping layer 26 and FIG. 6 finally shows a second hard mask layer 30 located upon the second surface semiconductor layer 28.

Within the embodiment, the dielectric capping layer 26 may comprise materials, have dimensions and be formed using methods that are conventional in the semiconductor fabrication art. Such materials, dimensions and methods may be analogous, equivalent or identical to the materials, dimensions and methods used for forming the buried dielectric layer 12. Typically, the dielectric capping layer 26 comprises at least in part a silicon oxide material, or a laminate of materials that includes a silicon oxide material, that has a thickness from about 200 to about 1000 angstroms.

Similarly, the second surface semiconductor layer 28 may comprise semiconductor materials, have dimensions and be formed using methods that are analogous, equivalent or identical to the materials, dimensions and methods that are used for forming the surface semiconductor layer 14 that is illustrated in FIG. 1. Typically, the surface semiconductor layer 14 and the second surface semiconductor layer 28 are selected so that a semiconductor fin when etched from the second surface semiconductor layer 28 has a different sidewall crystallographic orientation in comparison with the semiconductor fins 14′ that are etched from the surface semiconductor layer 14.

For example, for an n-finFET a 100 semiconductor fin sidewall advantages an electron charge carrier mobility, while for a p-finFET a 110 semiconductor fin sidewall advantages a hole charge carrier mobility.

Similarly, the surface semiconductor layer 14 and the second surface semiconductor layer 28 will also have different dopant polarities so as to advantage use of the different crystallographic orientation sidewall surfaces with respect to a finFET operating parameter such as a charge carrier mobility. Notwithstanding the foregoing, the surface semiconductor layer 14 and the second surface semiconductor layer 28 may also comprise semiconductor materials having identical crystallographic orientations and dopant polarities.

Typically, the second surface semiconductor layer 28 results from laminating a thicker semiconductor layer upon the dielectric capping layer 26 and subsequently thinning the thicker semiconductor layer. The thinning may be effected using mechanical polish planarizing methods, chemical etching methods and aggregate methods thereof.

Finally, the second hard mask layer 30 may comprise hard mask materials, have dimensions and be formed using methods that are also conventional in the semiconductor fabrication art. Such materials, dimensions and methods may be analogous, equivalent or identical to the materials, dimensions and methods that are used for forming the hard mask layer 16 that is illustrated in FIG. 1. Typically, the second hard mask layer 30 comprises a silicon nitride hard mask material that has a thickness from about 300 to about 1000 angstroms.

FIG. 7 shows the results of patterning the second hard mask layer 30 and the second surface semiconductor layer 28 to form a second surface semiconductor layer 28′ and a second hard mask layer 30′ located aligned thereupon. The second hard mask layer 30 and the second surface semiconductor layer 28 may be patterned to form the second surface semiconductor layer 28′ and the second hard mask layer 30′ located aligned thereupon while using etch methods and etch materials that are conventional. The etch methods and etch materials may be analogous, equivalent or identical to the etch methods and materials that are used for forming the first hard mask layers 16′, the semiconductor fins 14′ and the alignment marks 14″ that are illustrated in FIG. 2 from the hard mask layer 16 and the surface semiconductor layer 14 that are illustrated in FIG. 1.

As is illustrated within the schematic cross-sectional diagram of FIG. 7, the second hard mask layer 30 and the second surface semiconductor layer 28 are patterned to form the second hard mask layer 30′ and the second surface semiconductor layer 28′ with a lateral dimension that leaves exposed the alignment marks 14″ for future alignment purposes.

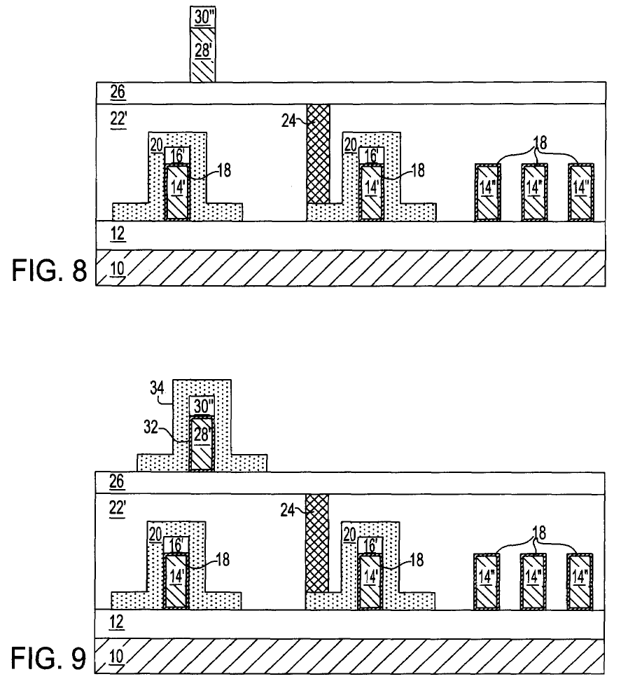

FIG. 8 shows the results of further patterning of the second hard mask layer 30′ and the second surface semiconductor layer 28′ to form a second hard mask layer 30″ and a second semiconductor fin 28″. Within the schematic cross-sectional diagram of FIG. 8, the second hard mask layer 30′ and the second surface semiconductor layer 28′ may be patterned to form the second hard mask layer 30″ and the second semiconductor fin 28″ while using etch methods and etch materials that are analogous, equivalent or identical to the etch methods and etch materials that are used for forming the second hard mask layer 30′ and the second surface semiconductor layer 28′ from the second hard mask layer 30 and the second surface semiconductor layer 28.

Although not specifically illustrated within the schematic cross-sectional diagram of FIG. 8, the patterning of the second hard mask layer 30′ and the second surface semiconductor layer 28′ to form the second hard mask layer 30″ and the second semiconductor fin 28″ is effected while using the series of alignment marks 14″ as alignment marks (i.e., in the aggregate the alignment marks 14″ comprise an “alignment mark”). By using the alignment marks 14″ for forming the second hard mask layer 30″ and the second semiconductor fin 28″, both the semiconductor fin 14′ and the second semiconductor fin 28″ may: (1) have a minimum critical dimension linewidth CD; and (2) be aligned to each other with overlap within the minimum critical dimension linewidth, or preferably a fraction of the minimum critical dimension linewidth CD. In contrast, when a three dimensional integrated circuit is fabricated using a conventional pre-fabricated layer laminating and transfer method, individual layers have an individual critical dimension variation and individual layers are of necessity fabricated separately with respect to their own individual series of alignment marks. A subsequent alignment of layer to layer while using alignment marks existing within individual layers provides for a minimum of two critical dimension variations tolerance when laminating and fabricating a laminated three dimensional integrated circuit not in accordance with the invention.

As is similarly also illustrated within the schematic cross-sectional diagram of FIG. 8, as a consequence of using the alignment marks 14″ for aligning a mask when forming the second semiconductor fin 28″, no alignment marks are formed from or used within the second surface semiconductor layer 28 (or any other upper lying semiconductor layer).

FIG. 9 shows a second gate dielectric 32 located upon the sidewalls of the second semiconductor fin 28″ and a second gate electrode 34 located upon the second gate dielectric 32 and spanning the second semiconductor fin 28″.

The second gate dielectric 32 may comprise materials, have dimensions and be formed using methods analogous, equivalent or identical to the materials, dimensions and methods used for fabricating the gate dielectrics 18. The second gate electrode 34 may comprise materials, have dimensions and be formed using methods analogous, equivalent or identical to the materials, dimensions and methods used for forming the gate electrodes 20.

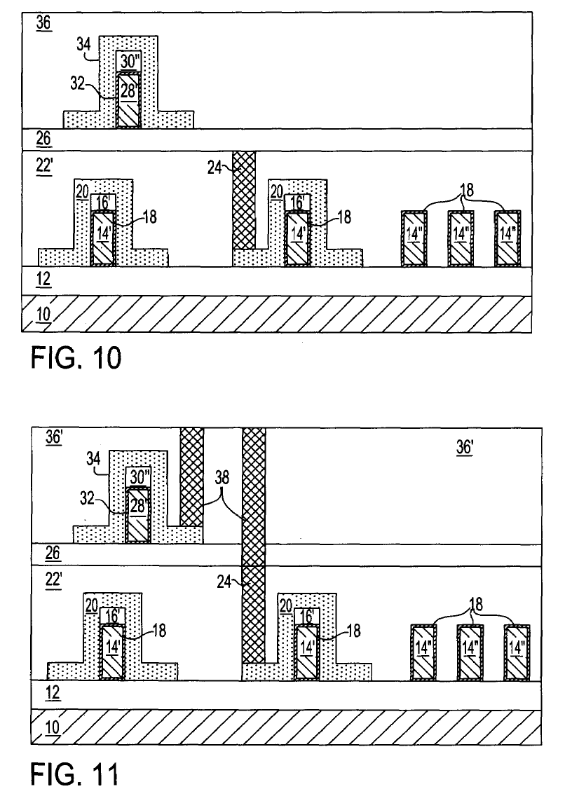

FIG. 10 shows a second passivating layer 36 located upon the semiconductor structure of FIG. 9.

The second passivating layer 36 may comprise materials, have dimensions and be formed using methods that are analogous, equivalent or identical to the materials, dimensions and methods used for forming the passivating layer 22 that is illustrated in FIG. 4.

FIG. 11 shows a plurality of second interconnect layers 38 penetrating the second passivating layer 36 and the dielectric capping layer 26 that are illustrated in FIG. 10 to thus form a second passivating layer 36′ and a dielectric capping layer 26′.

The second interconnect layers 38 may comprise materials, have dimensions and be formed using methods analogous equivalent or identical to the materials, dimensions and methods used for forming the interconnect layer 24. The second interconnect layers 38 are also aligned with respect to the second gate electrode 34 and the interconnect layer 24 while using the alignment marks 14 ″.

FIG. 11 shows a schematic cross-sectional diagram of a semiconductor structure in accordance with an embodiment of the invention. The semiconductor structure comprises a three dimensional semiconductor structure that is sequentially fabricated upon and over a semiconductor substrate while using a sequential semiconductor layer laminating and post-fabricating method rather than a pre-fabricated semiconductor layer laminating and transfer method. The semiconductor structure in accordance with FIG. 11 thus uses a single set of alignment marks 14″ (i.e., a single “alignment mark”) within a single substrate or a layer (i.e., laterally separated from a structure) for aligning all layers and structures within the semiconductor structure. No other alignment mark is formed within the semiconductor structure. By use of the single alignment mark, the semiconductor structure of FIG. 11 also allows for one critical dimensioned structure to be formed within each of a pair of vertically separated semiconductor layers or semiconductor devices, where the resulting pair of critically dimensioned structures is also aligned within a critical dimension separation distance.

In comparison, when using a more conventional pre-fabricated layer laminating and transfer method for forming a three-dimensional semiconductor structure or integrated circuit, individual semiconductor substrates or semiconductor layers are necessarily fabricated with their own alignment marks, and those alignment marks are in turn used for aligning the semiconductor substrate and semiconductor layers. Thus, within a conventional pre-fabricated layer laminating and transfer method for fabricating a three-dimensional integrated circuit, an overlay tolerance is additive and quantified to at least two critical dimension variations.

The preferred embodiment is illustrative of the invention rather than limiting of the invention. Revisions and modifications may be made to methods, materials, structures and dimensions of a semiconductor structure in accordance with the preferred embodiment, while still fabricating a semiconductor structure in accordance with the invention, further in accordance with the accompanying claims.

What is claimed is:

1. A semiconductor structure comprising:
a first device located over a substrate and having a first structure having a minimum linewidth; and
a second device located over the first device and having a second structure having the minimum linewidth, where an alignment of the first structure with respect to the second structure deviates by no more than the minimum linewidth.

2. The semiconductor structure of claim 1 wherein the first device has a first conductivity type and the second device has a second conductivity type the same as the first conductivity type.

3. The semiconductor structure of claim 1 wherein the first device has a first conductivity type and the second device has a second conductivity type different than the first conductivity type.

4. The semiconductor structure of claim 1 wherein the first device is a first field effect device and the second device is a second field effect device.

5. The semiconductor structure of claim 1 wherein the first field effect device is one of an n-finFET and a p-finFET and the second field effect device is the other of the n-finFET and the p-finFET.

6. The semiconductor structure of claim 5 wherein the first structure has a first crystallographic orientation and the second structure has a second crystallographic orientation different from the first crystallographic orientation.

7. A semiconductor structure comprising:
a first device located over a substrate and having a first structure located laterally separated from a first alignment mark also located over the substrate; and
a second device located over the first device and having a second structure absent a second alignment mark located laterally separated from the second structure.

8. The semiconductor structure of claim 7 wherein the first structure has a first minimum linewidth and the second structure has a second minimum linewidth.

9. The semiconductor structure of claim 7 wherein the first device has a first conductivity type and the second device has a second conductivity type the same as the first conductivity type.

10. The semiconductor structure of claim 7 wherein the first device has a first conductivity type and the second device has a second conductivity type different than the first conductivity type.

11. The semiconductor structure of claim 7 wherein the first device is a first field effect device and the second device is a second field effect device.

12. The semiconductor structure of claim 11 wherein the first field effect device is one of an n-finFET and a p-finFET and the second field effect device is the other of the n-finFET and the p-finFET.

13. The semiconductor structure of claim 8 wherein each of the first minimum linewidth and the second minimum linewidth comprises a fin linewidth.

14. A method for fabricating a semiconductor structure comprising:
forming over a substrate a first device comprising a first structure, the first structure being laterally separated from a first alignment mark;
forming over the first device a second semiconductor layer; and
patterning the second semiconductor layer while using the first alignment mark for aligning a second structure formed from the second semiconductor layer with respect to the first structure, the second structure being used within a second device located over the first device.

15. The method of claim 14 wherein the patterning the second semiconductor layer does not form a second alignment mark laterally separated from the second structure.

16. The method of claim 15 wherein the pattering the second semiconductor layer comprises:
patterning the second semiconductor layer to expose the first alignment mark; and
further patterning the second semiconductor layer while using the first alignment mark for aligning the second structure with respect to the first structure.

17. The method of claim 14 wherein the forming over the first device the second semiconductor layer includes laminating the second semiconductor layer over the first device.

18. The method of claim 14 wherein the forming the first device and the first alignment mark provide for a single step patterning of a first semiconductor layer.

19. The method of claim 14 wherein the forming the first device and the first alignment mark provide for a two step patterning of a first semiconductor layer.

20. The method of claim 19 wherein the two step patterning patterns the alignment mark separate from the first structure.
